(19) United States
(12) Patent Application Publication
(10) Pub. No.: US 2008/0308885 A1
(43) Pub. Date: Dec. 18, 2008

(54) MAGNETIC RANDOM ACCESS MEMORY AND FABRICATING METHOD THEREOF

(75) Inventor: Chao-Hung Lu, Hsinchu Hsien (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/761,573

(22) Filed: Jun. 12, 2007

(51) Int. Cl. H01L 43/00; H01L 21/00; H01L 29/82

(52) U.S. Cl. 257/421; 438/3; 257/E43.004; 257/E29.323; 257/E21.001

(57) ABSTRACT

A magnetic random access memory including a substrate, a first conductor layer, a magnetic layer, an insulating layer, a dielectric layer, two contacts and a second conductor layer is provided. The first conductor layer is disposed on the substrate. The magnetic layer is disposed on the first conductor layer. The insulating layer is disposed between the first conductor layer and the magnetic layer, and the thickness of the insulating layer is less than or equal to 1000 angstroms. The dielectric layer is disposed on the substrate and covers the magnetic layer, the insulating layer and the first conductor layer. The contacts are disposed in the dielectric layer and electrically connected to the first conductor layer and the magnetic layer respectively. The second conductor layer is disposed on the dielectric layer and includes two conductor patterns electrically connected to the corresponding contacts respectively.

### BACKGROUND OF THE INVENTION

1. Field of the Invention

The present invention relates to a memory and fabricating method thereof, and more particularly to a magnetic random access memory and fabricating method thereof.

2. Description of Related Art

In the past, dynamic random access memory (DRAM) is mainly used as the semiconductor memory in electronic machines such as the microcomputers due to its higher operating speed and integration. However, power is consumed when DRAM stores data. Moreover, the stored data will disappear after the power for driving the DRAM is cut off. Hence, DRAM cannot satisfy our demands for conserving energy or enhancing machine mobility in recent years. To meet the foregoing demands, an innovative memory having high operating speed, high degree of integration, low power consumption in addition to non-volatile characteristics is required.

The advantages of a magnetic random access memory (MRAM) includes non-volatile data storage, high integration level, high read/write speed and radioactive resistance. The method of writing data includes using two current wires, which is a bit line and a write word line, to sense a memory cell selected through the crossover of magnetic fields and change its magnetic resistance by changing the magnetizing direction of the magnetic material in the memory layer. To read memory data, a current is passed into the selected magnetic memory cell to read a resistance so that the digital value of the stored data can be determined according to the resistance. The MRAM memorizes information based on the direction of magnetization of a strong magnet. The information regarding the direction of magnetization can be electrically read using the substantially large magneto-resistance effect of a spin valve device or the tunneling magneto-resistance (TMR) effect if a magnetic tunnel junction (MTJ). Because the MRAM uses strong magnets, information can be stored permanently without consuming extra energy.

FIGS. 1A and 1B are schematic cross-sectional views showing a conventional method of fabricating a MRAM.

First, as shown in FIG. 1A, a patterned conductor layer 102 is formed on a substrate 100. Next, a dielectric layer 104 is formed on the substrate 100 to cover the patterned conductor layer 102. After that, a chemical-mechanical polishing process is performed to planarize the dielectric layer 104 and simultaneously reduce the thickness of the dielectric layer 104 above the patterned conductor layer 102.

Next, as shown in FIG. 1B, a patterned magnetic layer 106 is formed on the insulating layer 104 above the patterned conductor layer 102. Afterwards, a dielectric layer 108 is formed on the substrate 100. Next, contacts 110 and 112 are formed in the dielectric layer 108 and electrically connected to the patterned conductor layer 102 and the patterned magnetic layer 106 respectively. Thereafter, a patterned conductor layer 114 is formed on the dielectric layer 108. The patterned conductor layer 114 includes conductor patterns 116 and 118 electrically connected to the contacts 110 and 112 respectively.

In general, the dielectric layer 104 between the magnetic layer 106 and the patterned conductor layer 102 serves as an insulating layer and is polished to a thickness of about 2000 angstroms (Å). However, with this thickness, the MRAM consumes more power and operates at a slower speed, thereby leading to an inferior overall performance.

Although the dielectric layer 104 can be polished into a thinner layer in the foregoing chemical-mechanical polishing process, this will produce a greater variation in the thickness of the dielectric layer 104 and result in the lowering of yield and the reduction in productivity of the MRAM.

### SUMMARY OF THE INVENTION

Accordingly, the present invention is directed to a magnetic random access memory (MRAM) that can reduce power consumption.

The present invention is directed to a method of fabricating a magnetic random access memory (MRAM) that can effectively reduce the thickness of an insulating layer of the MRAM.

According to an embodiment of the present invention, a magnetic random access memory (MRAM) is provided. The MRAM includes a substrate, a first conductor layer, a magnetic layer, an insulating layer, a dielectric layer, two contacts and a second conductor layer. The first conductor layer is disposed on the substrate. The magnetic layer is disposed on the first conductor layer. The insulating layer is disposed between the first conductor layer and the magnetic layer, and the thickness of the insulating layer is less than or equal to 1000 angstroms (Å). The dielectric layer is disposed on the substrate and covers the magnetic layer, the insulating layer and the first conductor layer. The contacts are disposed in the dielectric layer and electrically connected to the first conductor layer and the magnetic layer respectively. The second conductor layer is disposed on the dielectric layer and includes two conductor patterns electrically connected to the corresponding contacts respectively.

According to the embodiment of the present invention, the thickness of the insulating layer in the MRAM is less than or equal to 500 Å.

According to the embodiment of the present invention, the thickness of the insulating layer in the MRAM is less than or equal to 200 Å.

According to the embodiment of the present invention, the thickness of the insulating layer in the MRAM is less than or equal to 50 Å.

According to the embodiment of the present invention, the substrate of the MRAM includes a silicon substrate.

According to the embodiment of the present invention, the material of the first conductor layer of the MRAM includes a metal.

According to the embodiment of the present invention, the material of the magnetic layer of the MRAM includes a metal.

According to the embodiment of the present invention, the materials of the insulating layer and the dielectric layer of the MRAM are different.

According to the embodiment of the present invention, the material of the insulating layer of the MRAM includes silicon oxide or silicon nitride.

According to the embodiment of the present invention, the material of the dielectric layer of the MRAM includes silicon oxide.

According to the embodiment of the present invention, the material of the second conductor layer of the MRAM includes a metal.

According to the embodiment of the present invention, the material of the contacts of the MRAM includes a metal.

The present invention also provides a method of fabricating a magnetic random access memory (MRAM). First, a first conductor material layer is formed on a substrate. Next, an insulating material layer is formed on the first conductor material layer. After that, a magnetic material layer is formed on the insulating material layer. Thereafter, a patterning process is performed on the magnetic material layer, the insulating material layer and the first conductor material layer respectively. Afterwards, a dielectric layer is formed on the substrate and covers the magnetic material layer, the insulating material layer and the first conductor material layer. Next, two contacts are formed in the dielectric layer and electrically connected to the first conductor material layer and the magnetic material layer. Subsequently, a conductor layer is formed on the dielectric layer. The conductor layer includes two conductor patterns electrically connected to the corresponding contacts respectively.

According to the embodiment of the present invention, in the foregoing method of fabricating the MRAM, the thickness of the insulating material layer is less than or equal to 1000 Å.

According to the embodiment of the present invention, in the foregoing method of fabricating the MRAM, the thickness of the insulating material layer is less than or equal to 500 Å.

According to the embodiment of the present invention, in the foregoing method of fabricating the MRAM, the thickness of the insulating material layer is less than or equal to 200 Å.

According to the embodiment of the present invention, in the foregoing method of fabricating the MRAM, the thickness of the insulating material layer is less than or equal to 50 Å.

According to the embodiment of the present invention, in the foregoing method of fabricating the MRAM, the method of forming the contacts includes the following steps. First, two openings are formed in the dielectric layer and expose a portion of the first conductor material layer and a portion of the magnetic material layer respectively. Next, a second conductor material layer is formed on the dielectric layer and fills in the openings. Thereafter, a portion of the second conductor material layer except the openings is removed.

According to the embodiment of the present invention, in the foregoing method of fabricating the MRAM, the method of forming the conductor layer includes the following steps. First, a third conductor material layer is formed on the dielectric layer. Next, a portion of the third conductor material layer is removed to leave a portion of the third conductor material layer above the contacts.

Accordingly, because the MRAM of the present invention has a thinner insulating layer, power consumption is reduced while the operating speed of the memory is increased. As a result, overall performance of the MRAM is improved.

Moreover, in the method of fabricating the MRAM in the present invention, the thickness of the insulating layer is already set when the insulating layer is formed. Hence, there is no need to adjust the thickness of the insulating layer by performing a chemical-mechanical polishing process as in the conventional method. Therefore, the thickness of the insulating layer can be effectively reduced and uniformity of the insulating layer can be effectively enhanced. In addition, the method of fabricating the MRAM according to the present invention is simpler than that of the conventional method. Consequently, the present invention can simplify the process of fabricating the MRAM.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A and 1B are schematic cross-sectional views showing a conventional method of fabricating a MRAM.

FIGS. 2A and 2D are schematic cross-sectional views showing a method of fabricating a MRAM according to an embodiment of the present invention.

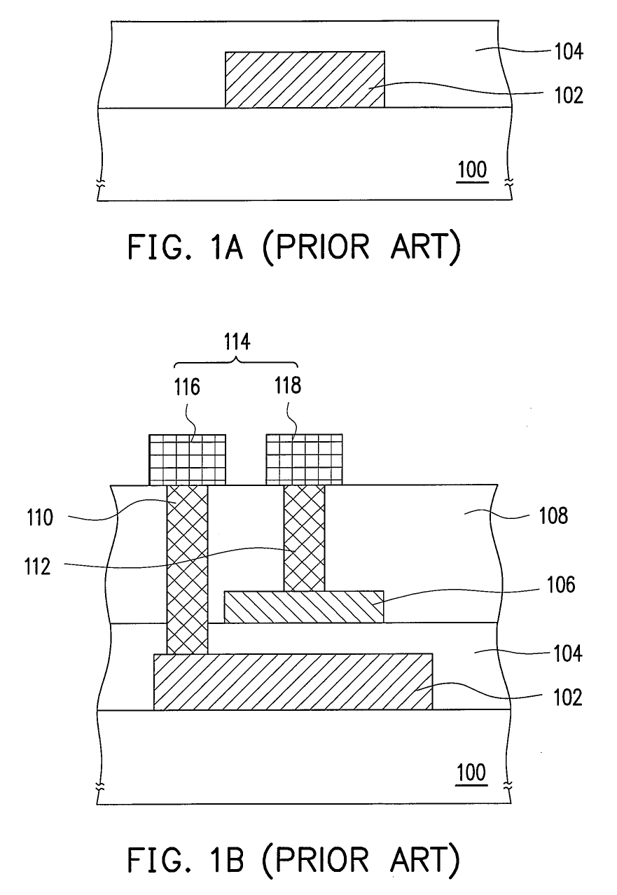

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

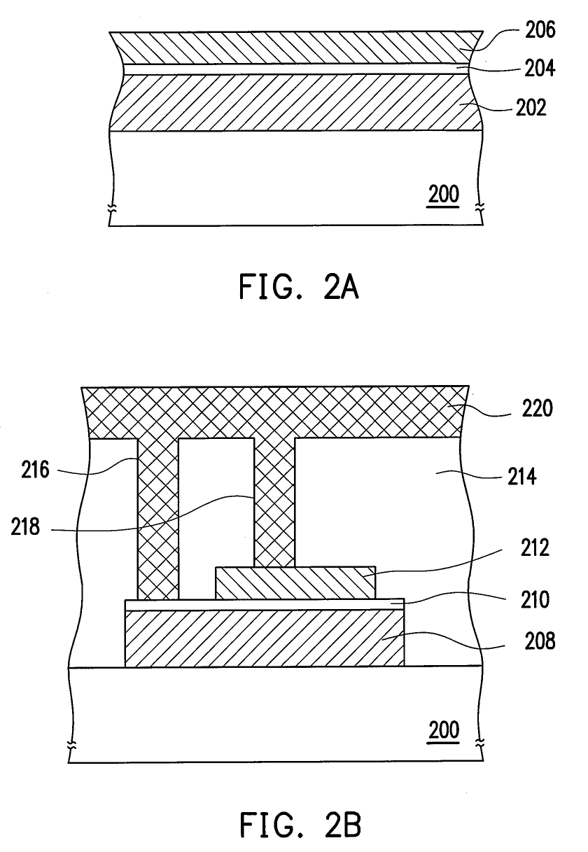

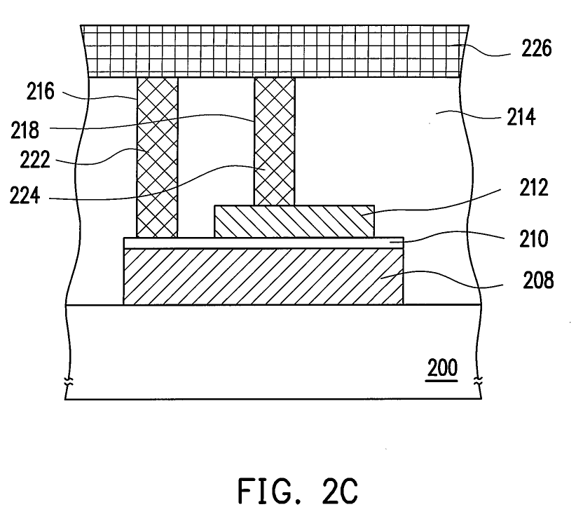

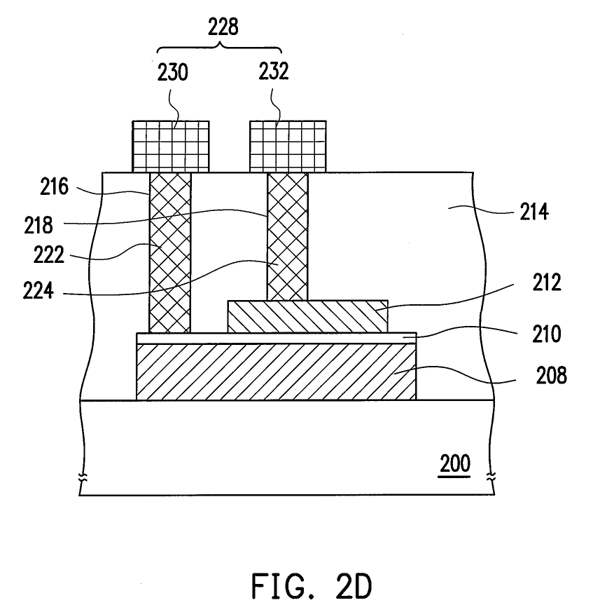

FIGS. 2A and 2B are schematic cross-sectional views showing a method of fabricating a MRAM according to an embodiment of the present invention.

First, as shown in FIG. 2A, a conductor material layer 202 is formed on a substrate 200. The substrate 200 is a silicon substrate, for example. The material of the conductor material layer 202 is a metal such as aluminum (Al) or other suitable conductor material. The method of forming the conductor material layer 202 is, for example, performing a physical vapor deposition process such as a sputtering process.

Next, an insulating material layer 204 is formed on the conductor material layer 202. The material of the insulating material layer 204 is an insulating material, for example, silicon oxide or silicon nitride. The method of forming the insulating material layer 204 is, for example, performing a chemical vapor deposition process. The thickness of the insulating material layer 204 is less than or equal to 1000 Å, for example. However, if the production quality of the film can be effectively controlled, the thickness of the insulating material layer 204 can be further reduced to less than or equal to 500 Å, less than or equal to 200 Å or even less than or equal to 50 Å.

Afterward, a magnetic material layer 206 is formed on the insulating material layer 204. The material of the magnetic material layer is a metal, for example, copper, iron, cobalt or nickel, or other suitable magnetic material. The method of forming the magnetic material layer 206 is, for example, performing a physical vapor deposition process such as a sputtering process.

Next, as shown in FIG. 2B, the magnetic material layer 206, the insulating material layer 204 and the conductor material layer 202 are patterned to form, from top to bottom, a magnetic layer 212, an insulating layer 210 and a conductor layer 208 over the substrate 200. The width of the magnetic layer 212 is, for example, smaller than that of the insulating layer 210 or the conductor layer 208, and the magnetic layer 212 exposes a portion of the insulating layer 210. The method of patterning the film layers is, for example, performing the conventional photolithographic and etching processes. Since these conventional photolithographic and etching processes should be familiar to those skilled in the art, a detailed description is omitted.

Thereafter, a dielectric layer 214 is formed on the substrate 200 and covers the magnetic layer 212, the insulating layer 210 and the conductor layer 208. The material of the dielectric layer 214 is, for example, different from that of the insulating layer 210. The material of the dielectric layer 214 is silicon oxide, for example. The method of forming the dielectric layer 214 is, for example, performing a chemical vapor deposition process.

Next, openings 216 and 218 are formed in the dielectric layer 214 and expose a portion of the conductor layer 208 and a portion of the magnetic layer 212 respectively. The method of forming the openings 216 and 218 is, for example, performing a conventional photolithographic process and an etching process. A detailed description thereof is thus omitted herein.

Afterwards, a conductor material layer 220 is formed on the dielectric layer 214 and fills in the openings 216 and 218. The material of the conductor material layer 220 is a metal such as tungsten.

Referring to FIG. 2C, a portion of the conductor material layer 220 except the openings 216 and 218 is removed to form contacts 222 and 224 in the dielectric layer 214. The contacts 222 and 224 are electrically connected to the conductor layer 208 and the magnetic layer 212. The method of removing the portion of the conductor material layer 220 is, for example, performing a conventional photolithographic process and an etching process. A detail description thereof is thus omitted herein.

Subsequently, a conductor material layer 226 is formed on the dielectric layer 214. The material of the conductor material layer 226 is a metal such as aluminum (Al) or other suitable conductor material. The method of forming the conductor material layer 226 is, for example, performing a physical vapor deposition process such as a sputtering process.

Referring to FIG. 2D, next, a portion of the conductor material layer 226 is removed to leave a portion of the conductor material layer 226 above the contacts 222 and 224 so as to form a conductor layer 228. The conductor layer 228 includes conductor patterns 230 and 232 electrically connected to the contacts 222 and 224 respectively. The portion of the conductor material layer 226 is removed by performing, for example, a conventional photolithographic process and an etching process. A detailed description thereof is thus omitted herein.

Since the insulating layer 210 of the MRAM is directly formed to the required thickness in the foregoing embodiment, the thickness of the insulating layer 210 can be effectively reduced and uniformity of the insulating layer 210 can be enhanced. Moreover, the method described in the foregoing embodiment can simplify the process of fabricating the MRAM.

In the following, FIG. 2D is used to describe an MRAM according to the present invention.

As shown in FIG. 2D, the MRAM includes a substrate 200, a conductor layer 208, an insulating layer 210, a magnetic layer 212, a dielectric layer 214, contacts 222 and 224 and a conductor layer 228. The conductor layer 208 is disposed on the substrate 200 and can be used as a word line. The magnetic layer 212 is disposed on the conductor layer 208 and its direction of magnetization can be used to memorize information. The insulating layer 210 is disposed between the conductor layer 208 and the magnetic layer 212 and the thickness of the insulating layer 210 is less than or equal to 1000 Å. The insulating layer 210 can effectively isolated the conductor layer 208 from the magnetic layer 212. The smaller the thickness of the insulating layer 210, the smaller the amount of energy required to operate the MRAM is so that considerable energy can be saved. In other embodiments, the thickness of the insulating layer 210 can be less than or equal to 500 Å, less than or equal to 200 Å or less than or equal to 50 Å. The dielectric layer 214 is disposed on the substrate 200 and covers the magnetic layer 212, the insulating layer 210 and the conductor layer 208. The contacts 222 and 224 are disposed in the dielectric layer 214 and electrically connected to the conductor layer 208 and the magnetic layer 212 respectively. The conductor layer 228 is disposed on the dielectric layer 214 and includes conductor patterns 230 and 232. The conductor patterns 230 and 232 are electrically connected to the corresponding contacts 222 and 224. Since the materials of various components and the method of forming the MRAM have been described before, a detailed description is omitted.

Accordingly, because the thickness of the insulating layer 210 of the MRAM is reduced, lower electrical power can be used to operate the MRAM and the operating speed of the MRAM can be increased. Consequently, overall performance of the MRAM is improved.

In summary, the advantages of the present invention at least include:

1. The MRAM of the present invention has the merits of low power consumption and high operating speed, and can improve overall performance of the MRAM.

2. The method of fabricating the MRAM according to the present invention can effectively reduce the thickness of the insulating layer.

3. The method of fabricating the MRAM according to the present invention can simplify the process of fabricating the MRAM.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A magnetic random access memory, comprising:
a substrate;
a first conductor layer, disposed on the substrate;
a magnetic layer, disposed on the first conductor layer; and
an insulating layer, disposed between the first conductor layer and the magnetic layer, wherein the insulating layer has a thickness less than or equal to 1000 Å;
a dielectric layer, disposed on the substrate and covering the magnetic layer, the insulating layer and the first conductor layer;
two contacts, disposed in the dielectric layer and electrically connected to the first conductor layer and the magnetic layer respectively; and
a second conductor layer, disposed on the dielectric layer and comprising two conductor patterns electrically connected to corresponding contacts respectively.

2. The magnetic random access memory according to claim 1, wherein the thickness of the insulating layer is less than or equal to 500 Å.

3. The magnetic random access memory according to claim 1, wherein the thickness of the insulating layer is less than or equal to 200 Å.

4. The magnetic random access memory according to claim 1, wherein the thickness of the insulating layer is less than or equal to 50 Å.

5. The magnetic random access memory according to claim 1, wherein the substrate comprises a silicon substrate.

6. The magnetic random access memory according to claim 1, wherein a material of the conductor layer comprises metal.

7. The magnetic random access memory according to claim 1, wherein a material of the magnetic layer comprises metal.

8. The magnetic random access memory according to claim 1, wherein a material of the insulating layer is different from a material of the dielectric layer.

9. The magnetic random access memory according to claim 1, wherein a material of the insulating layer comprises silicon oxide or silicon nitride.

10. The magnetic random access memory according to claim 1, wherein the material of the dielectric layer comprises silicon oxide.

11. The magnetic random access memory according to claim 1, wherein a material of the second conductor layer comprises a metal.

12. The magnetic random access memory according to claim 1, wherein a material of the contacts comprises a metal.

13. A method of fabricating a magnetic random access memory, comprising:
forming a first conductor material layer on a substrate;
forming an insulating material layer on the first conductor material layer;
forming a magnetic material layer on the insulating material layer;
patterning the magnetic material layer, the insulating material layer and the first conductor material layer respectively;
forming a dielectric layer on the substrate, the dielectric layer covering the magnetic material layer, the insulating material layer and the first conductor material layer;
forming two contacts in the dielectric layer, the contacts electrically connected to the first conductor material layer and the magnetic material layer respectively; and
forming a conductor layer on the dielectric layer, the conductor layer comprising two conductor patterns, each of the conductor patterns electrically connected to a corresponding contact respectively.

14. The method of fabricating the magnetic random access memory according to claim 13, wherein a thickness of the insulating material layer is less than or equal to 1000 Å.

15. The method of fabricating the magnetic random access memory according to claim 13, wherein the thickness of the insulating material layer is less than or equal to 500 Å.

16. The method of fabricating the magnetic random access memory according to claim 13, wherein the thickness of the insulating material layer is less than or equal to 200 Å.

17. The method of fabricating the magnetic random access memory according to claim 13, wherein the thickness of the insulating material layer is less than or equal to 50 Å.

18. The method of fabricating the magnetic random access memory according to claim 13, wherein the step of forming the contacts comprises:
forming two openings in the dielectric layer, the openings exposing a portion of the first conductor material layer and a portion of the magnetic material layer respectively;
forming a second conductor material layer, the second conductor material layer filling in the openings; and
removing a portion of the second conductor material layer except the openings.

19. The method of fabricating the magnetic random access memory according to claim 13, wherein the step of forming the conductor material layer comprises:
forming a third conductor material layer; and
removing a portion of the third conductor material layer to leave a portion of the third conductor material layer above the contacts.
